(19) United States
(12) Patent Application Publication
(10) Pub. No.: US 2026/0150389 A1
(43) Pub. Date: May 28, 2026

(54) INTEGRATED CIRCUIT ARRANGEMENT HAVING A REDUCTION OF AN INJECTION OF CHARGE CARRIERS IN A SEMICONDUCTOR SUBSTRATE

(71) Applicant: TDK-Micronas GmbH, Freiburg (DE)

(72) Inventor: Suhas SHINDE, Germering (DE)

(73) Assignee: TDK-Micronas GmbH, Freiburg (DE)

(21) Appl. No.: 19/402,482

(22) Filed: Nov. 26, 2025

(30) Foreign Application Priority Data
Nov. 26, 2024 (DE) 10 2024 003 916.3

(51) Int. Cl. H10D 84/80; H03K 17/687; H10D 8/25; H10D 30/65; H10D 62/10

(52) U.S. Cl. CPC H10D 84/811; H03K 17/6871; H10D 8/25; H10D 30/65; H10D 62/106

(57) ABSTRACT

An integrated circuit arrangement is formed, which has a reduction of an injection of charge carriers in a semiconductor substrate. The circuit arrangement includes a first half-bridge and a second half-bridge connected to form a full bridge, the drain connections of the first transistors and the source connections of the second transistors being electrically connected. The two parallel-connected source connections of the two second transistors are connected to a first connection of an electrical resistor having two connections, while the second connection of the electrical resistor forms a connection for a negative supply voltage or a ground potential. A Zener diode is connected between the source connection supply voltage and the gate connections on at least one of the first MOS transistors. The transistors are surrounded by at least one guard ring.

This nonprovisional application claims priority under 35 U.S.C. § 119(a) to German Patent Application No. 10 2024 003 916.3, which was filed in Germany on Nov. 26, 2024, and which is herein incorporated by reference.

### BACKGROUND OF THE INVENTION

### Field of the Invention

The invention relates to an integrated circuit arrangement having a reduction of an injection of charge carriers in a semiconductor substrate.

### Description of the Background Art

A circuit arrangement comprising a full bridge, also referred to as an H-bridge, is used to operate an electric motor. The full bridge is known to comprise two half-bridges. The circuit arrangement, and thus the H-bridge, is generally implemented by means of silicon technology, the silicon technology comprising a silicon substrate.

One connection of a winding or coil of the electric motor is connected to each connection, hereinafter also referred to as a tap, of the two half-bridges.

During load changes or rotational speed changes, H-bridge arrangements have the problem that the inductance of the winding or coil initially keeps the current constant. This results in voltage fluctuations at the taps of the half-bridges. The so-called well diodes of the transistors used, which are intrinsically present in silicon technology, or freewheeling diodes connected separately between the source and drain, limit the voltage fluctuations by facilitating a current flow.

Circuit arrangements of this type are known in the prior art. DE 102 27 832 C1 discloses a bridge circuit having four MOS transistors. US 2010/0 019 318 A1 discloses a structural element design having deep trench structures.

US 2002/0 158 600 A1 discloses an arrangement with three half-bridges, which is used for operating a brushless DC motor in a PWM mode. The brushless DC motor has three windings in a star circuit, which are each connected to the taps of the three half-bridges. The freewheeling diodes are each connected in parallel to the drain and source connections of the six MOS transistors used.

The source connections of the lower MOS transistors of the half-bridges (low-side drivers) are all three combined into a node and separated by a resistor from the supply with the ground connection.

To minimize the power drop in the current measuring resistor, it is advantageous to design the resistance value to be as low as possible.

Due to the requirements with regard to power and voltage resistance, the MOS transistors of the half-bridges are designed in modern CMOS technologies as LDNMOS transistors (laterally diffused NMOS) having one or multiple trench-isolated guard rings. In this way, the transistors which form the half-bridges, together with the further analog and digital circuit parts, may be monolithically integrated into a CMOS substrate to form an individual motor control IC.

The degree of integration is advantageously increased, since the miniaturization achieved increases the flexibility in designing the electric motor.

However, one fundamental disadvantage of this approach is that a parasitic NPN transistor is formed by the arrangement.

The emitter connection of the parasitic NPN transistor is formed by the tap of the half-bridge, or by the series connection of the upper LDNMOS transistor (high side) and the lower LDNMOS transistor (low side) to form this node. The source connection of the upper transistor and the drain connection of the lower transistor are electrically connected and form the tap of the half-bridge.

The base connection of the parasitic NPN transistor is formed by the p-type substrate.

The collector connection is typically formed as a multicollector by the isolated n-type wells surrounding the LDNMOS transistor.

Depending on the potential situation, the parasitic NPN transistor is enabled to inject minority charge carriers into the substrate region of the LDNMOS transistor. In other words, the parasitic NPN transistor becomes conductive.

The load change described at the outset when deactivating the supply of current to a winding of the electric motor favors the activation of the parasitic NPN transistor in that the winding inductance of the electric motor initially maintains the deactivated current, which results in a reduction of the potential in the tap of the half-bridge.

Only when the potential of the tap reaches approximately −0.7 to −0.8 volts does the freewheeling diode of the lower LDNMOS transistor become conductive and limit the drop in potential until the winding inductance is completely discharged, or its magnetic field is degraded.

The potential reduction to up to −0.8 voltages is, however, generally sufficient to activate the parasitic NPN transistor, in that the injection of minority charge carriers in the p-type substrate in the region of the LDNMOS transistor is set in motion.

The formation of a conductive path by injecting charge carriers must be avoided for efficiency reasons and furthermore also to protect the structural element against a malfunction, since the parasitic current is supplied from the multicollector connections of the surrounding n-type wells.

The surrounding n-type wells typically have the aforementioned digital and analog circuit parts of the IC. In particular, sensitive analog circuits, as well as digital circuits, may malfunction due to the activation of the parasitic transistor.

To avoid this type of malfunction or influence, circuit parts are placed at a great distance from LDNMOS transistors. In addition, guard rings are used, which are intended to remove the minority charge carriers injected into the p-type substrate.

However, studies show that guard rings do not always work reliably, in particular in combination with a trench isolation, and therefore offer only insufficient protection against the undesirable activation of the parasitic transistor.

In common designs of the silicon technology, the depth of the trench is greater than the depth of the n-type wells to establish a good well isolation, the depth of the trench sometimes being larger by more than 20 μm in a p-type substrate semiconductor wafer.

As a result, the trenches represent an excellent side wall isolation for the n-type wells, without using expensive SOI semiconductor wafers. A filling of the trenches with doped polysilicon and generally contacting them with a ground potential furthermore achieves a good field isolation.

The diodes poled in the non-conducting direction with the aid of the guard rings between the n-type wells and the p-type substrate form a depletion zone, which can easily protrude up to 5 μm and more into the p-type substrate.

However, it is disadvantageous that the trenches form a barrier for the electrons injected into the p-type substrate, over which they are unable to enter the active region of the guard rings or the depletion zone of the guard ring diodes.

Depending on the arrangement and geometry of the guard ring surfaces, a portion of the electrons enters the surrounding n-type wells and forms an undesirable parasitic current path due to their multicollector function, in that the parasitic bipolar transistors become conductive during the freewheeling phase.

It is understood that the mode of action is identical even in the case of an n-type substrate and injected holes as minority charge carriers of a parasitic PNP transistor and otherwise inverse signs.

### SUMMARY OF THE INVENTION

It is therefore an object of the present invention to refine the existing prior art and, in particular, to suppress the formation of a parasitic current path.

According to an example of the invention, an integrated circuit arrangement is provided, which has a reduction of an injection of charge carriers in a semiconductor substrate.

The circuit arrangement includes at least four MOS field-effect transistors interconnected to form a bridge circuit. Each of the four MOS transistors has a drain connection, a source connection, and a gate connection.

Two first transistors and two second transistors of the four MOS transistors are each connected in series to form a tap node with the aid of an electrical connection of the source connection of a first transistor and the drain connection of a second transistor and form a first half-bridge and a second half-bridge.

The first half-bridge and the second half-bridge can be connected in parallel to form a full bridge, in that the drain connections of the first transistors and the source connections of the second transistors are electrically connected.

The two half-bridges form two output connections with the two tap nodes and can be connected in each case to two connections of a winding of an electric motor in an operating position.

The two parallel-connected drain connections of the first transistors form a connection for a positive supply voltage of the full bridge.

The two parallel-connected source connections of the second transistors can be connected to a first connection of an electrical resistor having two connections, while the second connection of the electrical resistor forms a connection for a negative supply voltage or a ground potential.

On at least one of the first MOS transistors, a Zener diode can be connected between the source connection supply voltage and the gate connection, the cathode of the Zener diode being connected to the gate connection and the anode of the Zener diode to the source connection.

The transistors are designed as lateral double-diffused (LDD) n-type or p-type MOS field-effect transistors in p-type or n-type wells in a p-type or n-type semiconductor substrate and are surrounded by at least one guard ring, i.e., completely or almost completely enclosed.

The guard ring or multiple guard rings, preferably exactly two guard rings, and the transistors can be isolated from each other by deep trench structures, the deep trench structures being designed in such a way that the deep trench structure extends in each case over the boundary surface between the p-type or n-footwell and the semiconductor substrate and into the p-type or n-type semiconductor structure.

The guard ring or guard rings can be each designed as contacted n-type or p-type wells on the p-type or n-type substrate.

Further P-type or n-type wells, which are isolated with the aid of deep trench structures, can be arranged around the guard ring or guard rings, and analog or digital circuits are implemented in the further isolated p-type or n-type wells.

It should be noted that the series connection of a shared resistor between the source connections of the half-bridges and the negative supply voltage or ground generates a voltage negative feedback, which increases the potential for using the freewheeling phase. This counteracts a modulation of the parasitic emitter node in the direction of negative values. In other words, the activation of the parasitic bipolar transistor is counteracted.

To summarize, a circuit arrangement made up of MOS field-effect transistors interconnected to form a full bridge is provided for the purpose of driving the electric motor, in which the lower supply voltage node or the ground or the lower potential is implemented by a resistor separately from the low-side source connection.

A further advantage of the device according to the invention is that, particularly in combination with the Zener diode acting as a voltage limiter for the gate potential, a charging current is no longer removed in a parasitic manner for charging the gate connection of the upper LDNMOS transistor.

If a charging current over the Zener diode decreases due to the series-connected parasitic current path, PWM control pulses of an integrated motor controller may be attenuated or completely suppressed at the gate connection. As a result, a malfunction of the electric motor occurs.

The deep trench structures can extend beyond the boundary surface and into the p-type or n-type semiconductor substrate by at least 5 μm or at least 10 μm.

It should be noted that a difficult-to-overcome barrier, which impairs the effectiveness of the guard ring, occurs for the injected minority charge carriers due to a vertical extension of the deep trench structures into the p-type or n-type substrate, which significantly exceeds the extension of the space-charge zone of the guard ring diode at the pn junction between the n/p-type well and the P/N-type substrate in the direction of the p-type or n-type substrate.

A Zener diode can be connected between the source connections and the particular gate connections in both of the first MOS transistors.

Due to the typical value range of the control currents even in microdrives, it is advantageous that the resistance is in a range between 100 and 180 milliohms to generate an effective voltage swing in the range of some 100 mV.

The device can be formed by more than two half-bridges. In this case, the half-bridges are each connected in parallel, and the particular source connection of the second transistors is electrically connected to the resistor.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a view of a specific embodiment according to the invention of the integrated circuit arrangement for reducing the charge carrier injection in a semiconductor substrate; and

FIG. 2 shows a view of a cross-section of an LDNMOS transistor having guard rings in a deep trench technology.

### DETAILED DESCRIPTION

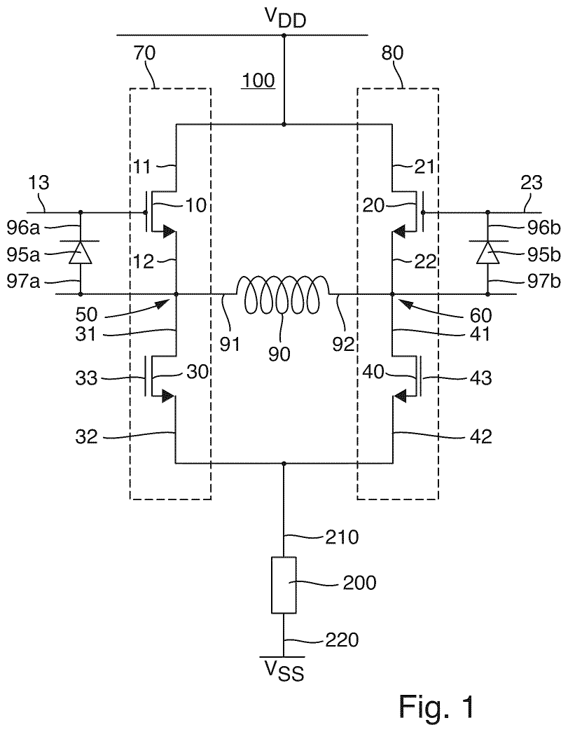

The illustration in FIG. 1 shows a schematic view of a first specific embodiment of an integrated circuit arrangement for reducing the charge carrier injection in a semiconductor substrate, which includes at least four MOS field-effect transistors 10, 20, 30, 40 interconnected to form a bridge circuit.

Each of the four MOS transistors 10, 20, 30, 40 has a drain connection 11, 21, 31, 41, a source connection 12, 22, 32, 42 and a gate connection 13, 23, 33, 43. Two first transistors 10, 20 and two second transistors 30, 40 of the four MOS transistors 10, 20, 30, 40 are each connected in series by electrically connecting source connection 12, 22 of first transistor 10, 20 and drain connection 31, 41 of second transistor 30, 40 to form two tap nodes 50, 60.

A first half-bridge 70 and a second half-bridge 80 are formed by the series circuit. First half-bridge 70 and second half-bridge 80 are connected in parallel to form a full bridge 100, in that drain connections 11, 21 of first transistors 10, 20 and source connections 32, 42 of the second transistors 30, 40 are electrically connected.

The two half-bridges 70, 80 having the two tap nodes 50, 60 are each connected to two connections 91, 92 of a winding 90 of an electric motor in the operating position. The two parallel-connected drain connections 11, 21 of the first transistors 10, 20 form a connection for a positive supply voltage VDD of full bridge 100.

The two parallel-connected source connections 32, 42 of the second transistors 30, 40 are connected to a first connection 210 of an electrical resistor 200 having two connections 210, 220. Second connection 220 of electrical resistor 200 forms a connection for a negative supply voltage VSS. A Zener diode 95a, 95b is connected in each case between source connections 50, 60 and particular gate connections 13, 23 on first MOS transistors 10, 20. Particular cathode 96a, 96b of Zener diodes 95 is electrically connected in each case to gate connection 13, 23 of first MOS transistors 10, 20, and particular anode 97a, 97b of Zener diodes 95 is connected in each case to source connections 50, 60.

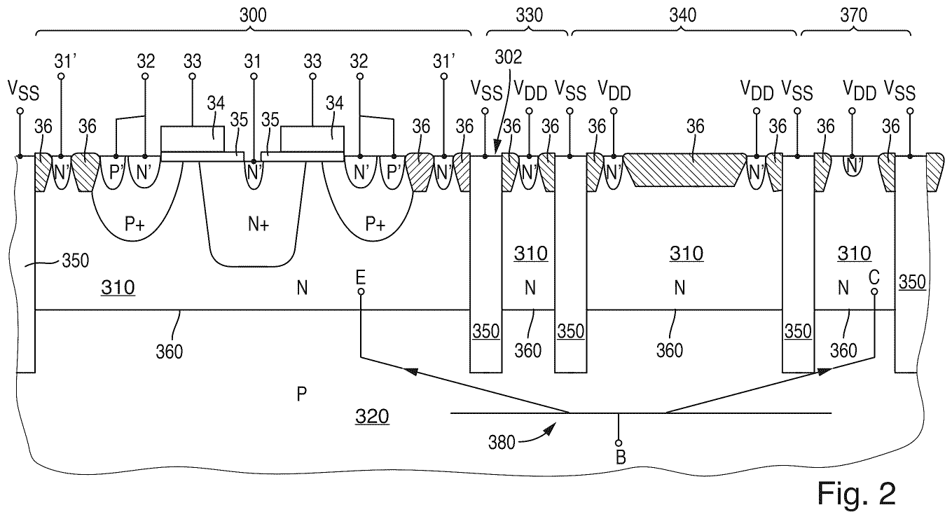

The illustration in FIG. 2 shows a schematic view of a cross-section of an LDNMOS transistor 300 having guard rings 330 and 340 as well as a further directly adjacent region 370 with digital and analog circuits. The carrier of the arrangement is a p-type semiconductor substrate 320. Multiple n-type wells 310 are introduced into the p-type substrate.

N-type wells 310 are separated from each other by multiple deep trenches 350 of an identical design. Deep trenches 350 protrude from a surface 302 through n-type wells 310 into p-type semiconductor substrate 320 for the purpose of electrical isolation.

Deep trenches 350 are typically filled with a conductive material and connected to ground VSS to avoid lateral field punchthrough. A pn junction 360 is formed in each case at the junction of p-type semiconductor substrate 320 to n-type wells 310. The arrangement is designed to be mirror-symmetrical to central drain connection 31 in cross-section in the region of LDNMOS transistor 300.

The structural element thus has two gate connections 33, which are connected to the two gate electrodes 34. Gate electrodes 34 are arranged on two gate oxide layers 35. Two source connections 32 are arranged in the connection to the gate oxide layers. Source connections 32 are characterized by a parallel circuit of a P-body connection. All semiconductor contacts on surface 302 have an n′ or p′ contact doping, depending on its type. Field oxide regions 36 are introduced into surface 302 outside drain, gate, and source regions.

Field-isolated contacts 31′ are connected in parallel to drain connection 31. P+ dopings typical of the structural element in the area of the channel region as well as an n+ drift zone on the drain side are represented next to contact n′ or p′ dopings in the area of LDNMOS transistor 300.

First guard ring 330 has a contacting, while second guard ring 340 is more expansive laterally and has two contacts.

Guard rings 330 and 340 surround the LDNMOS transistor in a point-symmetrical formation around central drain connection 31. A further region 370 abuts second guard ring 340, which is also designed as an n-type well, and in which the analog and digital circuit components of the IC are implemented.

The parasitic NPN transistor is formed as follows with reference to FIG. 1 and assuming that the illustrated LDNMOS transistor corresponds to transistor 30:

Region 370 represents a collector connection C of parasitic NPN transistor 380. Base B of parasitic NPN transistor 380 is formed by p-type semiconductor substrate 320. Emitter E of parasitic NPN transistor 380 is formed by the n-conducting connections in the area of LDNMOS transistor 300.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An integrated circuit arrangement having a reduction of an injection of charge carriers in a semiconductor substrate, the integrated circuit comprising:
at least four MOS field-effect transistors interconnected to form a bridge circuit, each of the at least four MOS transistors having a drain connection, a source connection, and a gate connection, wherein two first transistors of the at least four MOS field-effect transistors and two second transistors of the at least four MOS field effect transistors are connected in series to form two tap nodes by electrically connecting the source connection of each first transistor and the drain connection of each second transistor; and
a first half-bridge;
a second half-bridge, the first half-bridge and the second half-bridge being connected in parallel to form a full bridge, wherein the drain connections of the first transistors and the source connections of the second transistors are electrically connected;
at least one Zener diode;
at least one guard ring; and
at least one deep trench structure,
wherein the first and second half-bridges have the two tap nodes form two output connections and are each connected to two connections of a winding of an electric motor in an operating position,
wherein the two parallel-connected drain connections of the first transistors form a connection for a positive supply voltage of the full bridge,
wherein the two parallel-connected source connections of the second transistors are connected to a first connection of an electrical resistor having two connections,
wherein the second connection of the electrical resistor forms a connection for a negative supply voltage or a ground potential;
wherein the Zener diode is connected between the source connections and the gate connections on at least one of the first MOS field effect transistors,
wherein a cathode of the at least one Zener diode is electrically connected to the gate connection of the first MOS transistors, and an anode of the Zener diode is electrically connected to the source connection,
wherein the at least four MOS field effect transistors are designed as lateral double-diffused N- or P-MOS field-effect transistors in p-type or n-type wells in a p-type or n-type semiconductor substrate and are surrounded by the at least one guard ring,
wherein the at least one guard ring is designed as a contacted n-type or p-type well on the p-type or n-type substrate;
wherein the guard ring and the transistors are isolated by the at least one deep trench structure, and
wherein the deep trench structures are designed such that the deep trench structure extends over a boundary surface formed between the p-type or n-type well and the semiconductor substrate and into the p-type or n-type semiconductor structure,
wherein further p-type or n-type wells, which are isolated with the aid of deep trench structures, are arranged around the guard ring, and
wherein analog or digital circuits are implemented in the further isolated p-type or n-type wells.

2. The integrated circuit arrangement according to claim 1, wherein the deep trench structures extends beyond the boundary surface and into the semiconductor substrate by at least 5 μm or at least 10 μm.

3. The integrated circuit arrangement according to claim 1, wherein the Zener diode is connected between the source connections and the particular gate connections on both of the first transistors.

4. The integrated circuit arrangement according to claim 1, wherein more than two half-bridges are formed by a first transistor and a second transistor and are connected in parallel, and wherein a source connection of the second transistor is electrically connected to the resistor.

5. The integrated circuit arrangement according to claim 1, wherein exactly two guard rings are provided.
